(19) United States
(12) Patent Application Publication
(10) Pub. No.: US 2026/0220324 A1
(43) Pub. Date: Jul. 30, 2026

(54) Aero-Engine Limit Protection Control Method and Apparatus, Storage Medium and Device

(71) Applicant: DALIAN UNIVERSITY OF TECHNOLOGY, Dalian (CN)

(72) Inventors: Zhongyang FEI, Dalian (CN); Zhen WU, Dalian (CN); Ximing SUN, Dalian (CN); Lai WEI, Dalian (CN); Xian DU, Dalian (CN); Xuefang LIN, Dalian (CN)

(21) Appl. No.: 19/002,310

(22) Filed: Dec. 26, 2024

(30) Foreign Application Priority Data
Sep. 29, 2024 (CN) 202411369973.2

(51) Int. Cl. G06F 30/20

(52) U.S. Cl. CPC G06F 30/20

(57) ABSTRACT

An aero-engine limit protection control method and apparatus, a storage medium and a device belong to the technical field of aero-engine control. Through the design of a main controller and a limit controller, the present invention realizes the effects of tracking of high-pressure rotational speed and the limit of turbine outlet temperature respectively. A Lyapunov function is designed. The stability of a closed-loop system is analyzed under the average dwell-time restriction. Controller parameter conditions that satisfy stability analysis are obtained by solving inequalities. The proposed method not only realizes the purpose of limit protection control of the aero-engine in a transition stage and improves the safety of an aero-engine control system, but also theoretically analyzes the stability of the aero-engine limit protection control system and improves the reliability of engineering application.

### TECHNICAL FIELD

The present invention relates to the technical field of aero-engine control, and particularly relates to a novel limit protection control method and apparatus, a storage medium and a device.

### BACKGROUND

As a propulsion power plant, an aero-engine is widely used in important and critical fields. In the public research report of NASA, the control system of the aero-engine is divided into two parts: power management and limit management. As shown in FIG. 1, the power management module is mainly used for realizing closed-loop control of aero-engine rotational speed and accurate adjustment of engine thrust, and limit management is composed of a limit controller and selection logic. Taking an engine main control system as an example, the monitored variables include controlled variables (such as fan speed, engine pressure ratio, etc.) that characterize engine power and various limit variables (such as temperature, speed, pressure, etc.). Therefore, reasonable selection logic is needed for effective switching to ensure safe and stable operation, so as to not only ensure that the engine is operated within a limit range, but also ensure good dynamic quality, fast response, small overshooting, less oscillation, stability and reliability. As early as the 1990s, in the PCA program carried out by the NASA center, the aero-engine limit protection control research plan was first proposed, and the backup control system that took the engine as the main body was used for flight control in emergency situations. However, the existing research results have shown that the traditional limit protection control method can only ensure that the variable does not exceed the limit in a steady state, and cannot achieve the effect of limit protection in a transient state of the engine.

At present, aero-engines (such as GE90 and PW2000) generally adopt linear controllers and Max-Min to achieve limit protection control. This design can generally satisfy the requirements of the FAA for engine response time. However, in recent years, many researches have shown that this limit protection control system is conservative to a certain extent, and cannot make the engine play the best potential especially in emergency situations. In addition, in the existing research results, there is a lack of theoretical research related to the stability analysis of the aero-engine limit protection control system. To solve the above problems, the present invention provides a novel limit protection control method and apparatus, a storage medium and a device. The structure is shown in FIG. 2, and is applied to the temperature limit control of the turbofan aero-engine. The dynamic controller is designed to improve the limit protection control performance in the transition stage, and the stability analysis of the aero-engine limit protection control system is carried out by constraining controller switching, thereby improving the reliability of practical engineering application.

### SUMMARY

To ensure the safety and the stability of the operating process of the aero-engine, the present invention provides a novel limit protection control method and apparatus, a storage medium and a device used for the temperature limit control of the turbofan aero-engine.

The technical solution of the present invention is as follows:

An aero-engine limit protection control method comprises the following specific steps:
step 1: modeling of an aero-engine control system;
conducting linear system identification for an aero-engine according to input-output data near an operating point, and establishing a system model by using MATLAB software program calculation:

$$\{ \begin{matrix}\dot{n} ( t ) = An ( t ) + {Bw}_{f} ( t ) , \\ {T}_{4} ( t ) = Cn ( t ) + {Dw}_{f} ( t ) ,\end{matrix}$$

where n=[n₁ n₂]^{T}; n₁ and n₂ represent the increments of low-pressure rotational speed and high-pressure rotational speed of the aero-engine relative to a steady-state operating point respectively; w_{f} represents the fuel increment of the engine; T₄ represents the increment of the turbine outlet temperature of the engine; and A, B, C and D are identified system matrices; n represents a first-order derivative of n, and all the following characters with a dot represent the first-order derivative of the character;
the process of the step 1 is realized in MATLAB software;
step 2: design of a main controller;
extending a system state n and a control input w_{f} into a new state vector x, to obtain an extended system with speed output as follows:

$$\{ \begin{matrix}\dot{x} = \overline{A} x + \overline{B} {u}_{f} , \\ {n}_{2} = {\overline{C}}_{1} x ,\end{matrix}$$

where

$$x = [ \begin{matrix}{n}^{T} & {{w}_{f}^{T} ]}^{T}\end{matrix}$$

and u_{f}=\dot{w}_{f} represent the derivatives of fuel signal;

$$\overline{A} = [ \begin{matrix}A & B \\ 0 & 0\end{matrix} ] ; \overline{B} = [ \begin{matrix}0 \\ I\end{matrix} ] ; {\overline{C}}_{1} = [ \begin{matrix}{C}_{1} & 0 ] ; {C}_{1} = [ \begin{matrix}0 & 1 ] ;\end{matrix}\end{matrix}$$

defining a state tracking error as Δx=x−xₛ, where xₛ represents a target value to be tracked;
designing the derivatives of the fuel signal that satisfy the conditions:

$${u}_{f} = {k}_{1} {Θ}_{1} Δ x ,$$

where k₁>0 represents a controller gain;

$${Θ}_{1} = [ \begin{matrix}{0}_{2 \times 1} & 1\end{matrix} ] [ \begin{matrix}A & B \\ {C}_{1} & 0\end{matrix} ] ; {0}_{2 \times 1} = [ \begin{matrix}0 & 0\end{matrix} ] ;$$

calculating the main controller as follows:

$$\begin{matrix}{w}_{f} = {\int }_{0}^{t} {u}_{f} ( ε ) d ε \\ = {\int }_{0}^{t} {{k}_{1} [ {n}_{2} ( ε ) - {n}_{2 s} ( ε ) ]}^{T} d ε\end{matrix} ;$$

where n₂, represents a steady-state operating value of high-pressure rotational speed, and ε represents an integrating factor;
the process of the step 2 is realized in MATLAB software;
step 3: design of a temperature limit controller;
considering an extended system with temperature output as follows:

$$\{ \begin{matrix}\dot{x} = \overline{A} x + \overline{B} {u}_{f} , \\ {T}_{4} = {\overline{C}}_{2} x ,\end{matrix}$$

where C̅₂=[C D];
designing the derivatives of the fuel signal that satisfy the conditions:

$${u}_{f} = {k}_{2} {Θ}_{2} Δ x ,$$

where k₂>0 represents a controller gain;

$${Θ}_{2} = [ \begin{matrix}{0}_{2 \times 1} & 1\end{matrix} ] [ \begin{matrix}A & B \\ C & D\end{matrix} ] ;$$

calculating the temperature limit controller as follows:

$$\begin{matrix}{w}_{f} = {\int }_{0}^{t} {u}_{f} ( ε ) d ε \\ = {\int }_{0}^{t} {k}_{2} [ {T}_{4} ( ε ) - {T}_{4 s} ( ε ) ] d ε\end{matrix} ;$$

where T₄ₛ represents the limit value of the increment of the turbine outlet temperature;
the process of the step 3 is realized in MATLAB software;
step 4: stability analysis;
providing dwell-time restriction, formulating controller switching rules, analyzing the stability of the limit protection control system and providing stability conditions; for a closed-loop control system, when there is a Lyapunov function V_{σ}(Δx) with σ(t)∈{1,2} representing a controller switching signal, and real numbers α>0 and μ>1, satisfying conditions:
1) within a running interval Tₛ(tₖ,tₖ₊₁) of the main controller,

$${\dot{V}}_{i} ( Δ x ) \leq - α {V}_{i} ( Δ x ) ,$$

2) within a running interval Tₐ(tₖ,tₖ₊₁) of the temperature limit controller,

$${\dot{V}}_{i} ( Δ x ) \leq β {V}_{i} ( Δ x ) ,$$

3) at a switching time t=tₖ of the controller,

$${V}_{i} ( Δ x ) \leq μ {V}_{j} ( Δ x ) ,$$

where i∈{1, 2}, j∈{1, 2}, i≠j, and β represents an upper bound of a system energy growth rate;
when the above three conditions are satisfied, the following inequalities are true,

$${V}_{σ ( t )} ( Δ x ( t ) ) \leq exp \{ - α {T}_{s} ( {t}_{\tilde{N}} , t ) + β {T}_{a} ( {t}_{\tilde{N}} , t ) \} {V}_{σ ( {t}_{\tilde{N}} )} ( Δ x ( {t}_{\tilde{N}} ) ) \leq μ exp \{ - α {T}_{s} ( {t}_{\tilde{N}} , t ) + β {T}_{a} ( {t}_{\tilde{N}} , t ) \} {V}_{σ ( {t}_{\tilde{N} - 1} )} ( Δ x ( {t}_{\tilde{N}} ) ) \leq μ exp \{ - α {T}_{s} ( {t}_{\tilde{N} - 1} , t ) + β {T}_{a} ( {t}_{\tilde{N} - 1} , t ) \} {V}_{σ ( {t}_{\tilde{N} - 1} )} ( Δ x ( {t}_{\tilde{N} - 1} ) ) \leq ... \leq {μ}^{{N}_{σ} ( {t}_{0} , t )} exp \{ - α {T}_{s} ( {t}_{0} , t ) + β {T}_{a} ( {t}_{0} , t ) \} {V}_{σ ( {t}_{0} )} ( Δ x ( {t}_{0} ) )$$

where N_{σ}(t₀,t) represents the total number of switching within an interval [t₀,t); t_{Ñ} represents the last switching time within the interval [t₀,t);
due to t−t₀=Tₛ(t₀,t)+Tₐ(t₀,t), the following inequality can be obtained

$${V}_{σ ( t )} ( Δ x ( t ) ) \leq {μ}^{{N}_{σ} ( {t}_{0} , t )} exp \{ - α ( t - {t}_{0} ) + ( α + β ) {T}_{a} ( {t}_{0} , t ) \} {V}_{σ ( {t}_{0} )} ( Δ x ( {t}_{0} ) ) \leq {μ}^{{N}_{σ} ( {t}_{0} , t )} exp \{ - α ( t - {t}_{0} ) + ( α + β ) {N}_{σ} ( {t}_{0} , t ) \overline{τ} \} {V}_{σ ( {t}_{0} )} ( Δ x ( {t}_{0} ) ) ,$$

where τ̅>0 represents the maximum action duration of the temperature limit controller;
when τₐ>0 exists so that the controller switching process satisfies

$${N}_{σ} ( {t}_{0} , t ) \leq {N}_{0} + \frac{t - {t}_{0}}{{τ}_{a}} ,$$

N₀∈N and N represents a non-negative integer field, then the controller switching satisfies average dwell time switching, and

$${V}_{σ ( t )} ( Δ x ( t ) ) \leq exp \{ [ ln μ + ( α + β ) \overline{τ} ] {N}_{0} \} \times exp \{ ( \frac{ln μ + ( α + β ) \overline{τ}}{{τ}_{a}} - α ) ( t - {t}_{0} ) \} {V}_{σ ( {t}_{0} )} ( Δ x ( {t}_{0} ) ) ;$$

at this moment, when average dwell time satisfies the condition:

$${τ}_{a} > \frac{( α + β ) \overline{τ} + ln μ}{α} ,$$

then

$$\frac{ln μ + ( α + β ) \overline{τ}}{{τ}_{a}} - α < 0$$

and the Lyapunov function V_{σ}(Δx) decays to 0; at this moment, an aero-engine limit protection control system is stable:
to obtain a controller parameter condition that satisfies stability analysis, constructing the Lyapunov function for the closed-loop control system as follows:

$${V}_{i} ( Δ x ) = Δ {x}^{T} {U}_{i} Δ x ,$$

where

$${U}_{i} = {P}_{i}^{- 1} ,$$

and Pᵢ represents a given positive definite symmetric matrix;
for the given controller gains k₁ and k₂, when there are constants α>0, β>0 and μ>1 and the positive definite symmetric matrices P₁>0 and P₂>0 so that the following matrix inequalities are true, the aero-engine limit protection control system is stable;

$$α {P}_{1} + ( \overline{A} {P}_{1} + \overline{B} {k}_{1} {Θ}_{1} {P}_{1} ) + {( \overline{A} {P}_{1} + \overline{B} {k}_{1} {Θ}_{1} {P}_{1} )}^{T} \leq 0 ,$$

$$- β {P}_{2} + ( \overline{A} {P}_{2} + \overline{B} {k}_{2} {Θ}_{2} {P}_{2} ) + {( \overline{A} {P}_{2} + \overline{B} {k}_{2} {Θ}_{2} {P}_{2} )}^{T} \leq 0 ,$$

$${P}_{1} \leq μ {P}_{2} , {P}_{2} \leq μ {P}_{1} ;$$

the inequality solving process of the step 4 is realized in YALMIP software;
step 5: a control simulation experiment of a turbofan aero-engine to analyze control performance.

The simulation experiment of the step 5 is conducted in SIMULINK software.

An aero-engine limit protection control apparatus comprises:
a system identification module: used for system modeling and parameter identification of the aero-engine control system near an operating point by using real-time data of the aero-engine to obtain an aero-engine control system model which is convenient for controller design;
a main controller module: used for adjusting rotational speed of the aero-engine in a closed loop to satisfy the needs of aircraft for thrust change;
a temperature limit controller module: used for limiting the turbine outlet temperature of the aero-engine within a safety boundary to avoid the overtemperature operation of the aero-engine;
a stability analysis module: used for planning the switching process of the controller and verifying controller parameters to achieve the purpose of ensuring the stability of the aero-engine control system.

A computer-readable storage medium stores at least one instruction, at least one program, code set or instruction set, and the at least one instruction, the at least one program, the code set or the instruction set is loaded and executed by a processor to realize the above aero-engine limit protection control method.

A server comprises a processor and a memory, the memory stores at least one instruction, and the instruction is loaded and executed by the processor to realize the above aero-engine limit protection control method.

The present invention has the following beneficial effects: To ensure the safety and the stability of the operating process of the aero-engine, the present invention designs a novel limit protection control method. Through the design of the main controller and the limit controller, the effects of tracking of the high-pressure rotational speed and the limit of the turbine outlet temperature are realized respectively. The Lyapunov function is designed. The stability of the closed-loop system is analyzed under the average dwell-time restriction. The controller parameter conditions that satisfy stability analysis are obtained by solving the inequalities. The proposed method not only realizes the purpose of limit protection control of the aero-engine in the transition stage and improves the safety of the aero-engine control system, but also theoretically analyzes the stability of the aero-engine limit protection control system and improves the reliability of engineering application.

### DESCRIPTION OF DRAWINGS

FIG. 1 is a diagram of an aero-engine control structure;

FIG. 2 shows a proposed novel limit protection control structure;

FIG. 3 shows controller switching signals;

FIG. 4 is an increment response curve of high-pressure rotational speed;

FIG. 5 is an increment response curve of turbine outlet temperature.

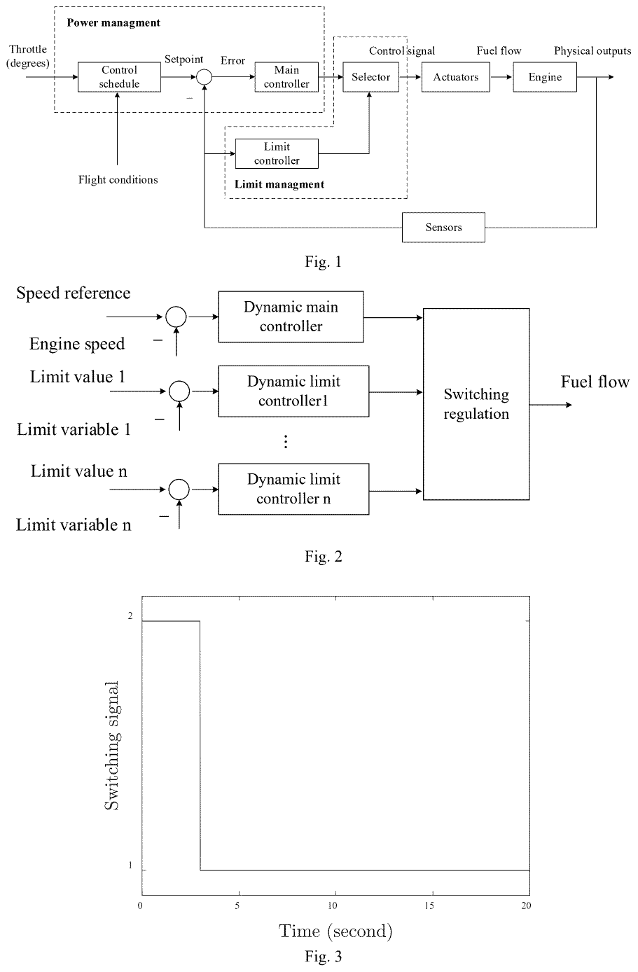

### DETAILED DESCRIPTION

Specific embodiments of the present invention are further described below in combination with the drawings and the technical solution.

Specific implementation steps:

### 1) Modeling of an Aero-Engine Control System in MATLAB Software;

The operating process of the aero-engine has the characteristic of strong nonlinearity, and the coupling relationship between parameters is serious, which makes it difficult to directly model the engine by mechanism. The present invention obtains the following linear system through real-time input-output data near the operating point of the engine by using MATLAB software and system identification calculation programs:

$$\{ \begin{matrix}\dot{n} ( t ) = A n ( t ) + B {w}_{f} ( t ) , \\ {T}_{4} ( t ) = C n ( t ) + D {w}_{f} ( t ) ,\end{matrix} \qquad ( 1 )$$

where n=[n₁ n₂]^{T}; n₁ and n₂ represent the increments of low-pressure rotational speed and high-pressure rotational speed of the aero-engine relative to a steady-state operating point respectively; w_{f} represents the fuel increment of the engine; T₄ represents the increment of the turbine outlet temperature of the engine; and A, B, C and D are identified system matrices;

### 2) Design of a Main Controller in MATLAB Software;

To realize closed-loop control of aero-engine rotational speed and accurate adjustment of thrust, a main controller needs to be designed for the limit protection control system. A system state n and a control input w_{f} are extended into a new state vector x to obtain an extended system with speed output as follows:

$$\{ \begin{matrix}\dot{x} = \overline{A} x + \overline{B} {u}_{f} , \\ {n}_{2} = {\overline{C}}_{1} x ,\end{matrix} \qquad ( 2 )$$

where

$$x = {[ \begin{matrix}{n}^{T} & {w}_{f}^{T}\end{matrix} ]}^{T}$$

and u_{f}=\dot{w}_{f} represent the derivatives of fuel signal;

$$\overline{A} = [ \begin{matrix}A & B \\ 0 & 0\end{matrix} ] ; \overline{B} = [ \begin{matrix}0 \\ I\end{matrix} ] ; {\overline{C}}_{1} = [ \begin{matrix}{C}_{1} & 0\end{matrix} ] ; {C}_{1} = [ \begin{matrix}0 & 1\end{matrix} ] ;$$

The state tracking error is defined as Δx=x−xₛ, where xₛ represents a target value to be tracked;
and the derivatives of the fuel signal are designed to satisfy the conditions:

$${u}_{f} = {k}_{1} {Θ}_{1} Δ x , \qquad ( 3 )$$

where k₁>0 represents a controller gain;

$${Θ}_{1} = [ \begin{matrix}{0}_{2 \times 1} & 1\end{matrix} ] [ \begin{matrix}A & B \\ {C}_{1} & 0\end{matrix} ] ; {0}_{2 \times 1} = [ \begin{matrix}0 & 0\end{matrix} ] ;$$

From formula (1), the following can be obtained:

$$x = {[ \begin{matrix}A & B \\ {C}_{1} & 0\end{matrix} ]}^{- 1} [ \begin{matrix}\dot{n} \\ {n}_{2}\end{matrix} ] ; \qquad ( 4 )$$

When the system is in a steady state, the following relational expression is obtained:

$${x}_{s} = {[ \begin{matrix}A & B \\ {C}_{1} & 0\end{matrix} ]}^{- 1} [ \begin{matrix}0 \\ {n}_{2 s}\end{matrix} ] ; \qquad ( 5 )$$

where n₂ₛ represents a steady-state operating value of high-pressure rotational speed;

From formula (4) and formula (5), the following is obtained:

$$Δ x = {[ \begin{matrix}A & B \\ {C}_{1} & 0\end{matrix} ]}^{- 1} [ \begin{matrix}\dot{n} \\ {n}_{2} - {n}_{2 s}\end{matrix} ] ; \qquad ( 6 )$$

From formula (3) and formula (6), the main controller is calculated as follows:

$$\begin{matrix}{w}_{f} = {\int }_{0}^{t} {u}_{f} ( ε ) d ε \\ = {\int }_{0}^{t} {{k}_{1} [ {n}_{2} ( ε ) - {n}_{2 s} ( ε ) ]}^{T} d ε\end{matrix} ; \qquad ( 7 )$$

where ε represents an integrating factor;

### 3) Design of a Temperature Limit Controller in MATLAB Software;

To limit the turbine outlet temperature of the aero-engine within a safety range, the design of the temperature limit controller needs to be researched in the limit protection control, and an extended system with temperature output is considered as follows

$$\{ \begin{matrix}\dot{x} = \overline{A} x + \overline{B} {u}_{f} , \\ {T}_{4} = {\overline{C}}_{2} x ,\end{matrix} \qquad ( 8 )$$

where C̅₂=[C D];
the derivatives of the fuel signal are designed to satisfy the conditions:

$${u}_{f} = {k}_{2} {Θ}_{2} Δ x , \qquad ( 9 )$$

where k₂>0 represents a controller gain;

$${Θ}_{2} = [ {0}_{2 \times 1} 1 ] [ \begin{matrix}A & B \\ C & D\end{matrix} ] ;$$

Similar to the design process of the main controller, a temperature limit controller is calculated as follows:

$$\begin{matrix}{w}_{f} = {\int }_{0}^{t} {u}_{f} ( ε ) d ε \\ = {\int }_{0}^{t} {k}_{2} [ {T}_{4} ( ε ) - {T}_{4 s} ( ε ) ] d ε\end{matrix} ; \qquad ( 10 )$$

where T₄ₛ represents the limit value of the increment of the turbine outlet temperature;

### 4) Stability Analysis in YALMIP Software;

In the proposed limit protection control method, the main controller is used for adjustment of the engine speed and thrust control, and the temperature limit controller is used for limiting the turbine outlet temperature of the engine to restrict the engine to operate in the safety range to avoid overtemperature failure. Therefore, in practical engineering application, there is a phenomenon of switching between the main controller and the temperature limit controller, which makes it difficult for stability analysis of the closed-loop control system. To solve this problem, the present invention restricts the switching frequency of the controllers based on average dwell time switching, analyzes the stability of the aero-engine limit protection control system and provides the inequalities for solving controller parameters that satisfy the stability conditions.

Firstly, when the aero-engine is operated in a steady state, the following relational expression exists:

$${\dot{x}}_{s} = \overline{A} {x}_{s} + \overline{B} {u}_{f s} , \qquad ( 11 )$$

where μ_{fs} represents the derivative value of corresponding fuel w_{fs} when the engine is operated in the steady state.

Obviously, there is a relational expression u_{fs}=\dot{w}_{fs}=0. From formula (2), formula (3), formula (8), formula (9) and formula (11), the closed-loop control system is obtained.

$$Δ \dot{x} = ( \overline{A} + \overline{B} {k}_{i} {Θ}_{i} ) Δ x , \qquad ( 12 )$$

where i={1,2}, i=1 represents that the main controller is activated, and i=2 represents that the temperature limit controller is activated.

For the closed-loop control system (12), when there is a Lyapunov function V_{σ}(Δx) with σ(t)∈{1,2} representing a controller switching signal, and real numbers α>0 and μ>1, the following conditions are satisfied:
1) within a running interval Tₛ(tₖ,tₖ₊₁) of the main controller,

$${\dot{V}}_{i} ( Δ x ) \leq - α {V}_{i} ( Δ x ) , \qquad ( 13 )$$

2) within a running interval Tₐ(tₖ,tₖ₊₁) of the temperature limit controller,

$${\dot{V}}_{i} ( Δ x ) \leq β {V}_{i} ( Δ x ) , \qquad ( 14 )$$

3) at a switching time t=tₖ of the controller,

$${V}_{i} ( Δ x ) \leq μ {V}_{j} ( Δ x ) , \qquad ( 15 )$$

where i∈{1,2}, j∈{1,2}, i≠j, and β represents an upper bound of a system energy increasing rate.

When the conditions of formula (13) to formula (15) are satisfied, the following inequalities are true,

$$\begin{matrix}{V}_{σ ( t )} ( Δ x ( t ) ) \leq exp \{ - α {T}_{s} ( {t}_{\tilde{N}} , t ) + β {T}_{a} ( {t}_{\tilde{N}} , t ) \} {V}_{σ ( {t}_{\tilde{N}} )} ( Δ x ( {t}_{\tilde{N}} ) ) \\ \leq μexp \{ - α {T}_{s} ( {t}_{\tilde{N}} , t ) + β {T}_{a} ( {t}_{\tilde{N}} , t ) \} {V}_{σ ( {t}_{\tilde{N} - 1} )} ( Δ x ( {t}_{\tilde{N}} ) ) \\ \leq μexp \{ - α {T}_{s} ( {t}_{\tilde{N} - 1} , t ) + β {T}_{a} ( {t}_{\tilde{N} - 1} , t ) \} {V}_{σ ( {t}_{\tilde{N} - 1} )} ( Δ x ( {t}_{\tilde{N} - 1} ) ) \\ \leq … \\ \leq {μ}^{{N}_{σ} ( {t}_{0} , t )} exp \{ - α {T}_{s} ( {t}_{0} , t ) + β {T}_{a} ( {t}_{0} , t ) \} {V}_{σ ( {t}_{0} )} ( Δ x ( {t}_{0} ) )\end{matrix} \qquad ( 16 )$$

where N_{σ}(t₀,t) represents the total number of switching within an interval [t₀, t); t_{Ñ} represents the last switching time within the interval [t₀,t);

In addition, due to t−t₀=Tₛ(t₀,t)+Tₐ(t₀,t) and Tₐ(t₀,t)≤N_{σ}(t₀,t)τ̅, from formula (16), the following inequality can be obtained

$$\begin{matrix}{V}_{σ ( t )} ( Δ x ( t ) ) \leq {μ}^{{N}_{σ} ( {t}_{0} , t )} exp \{ - α ( t - {t}_{0} ) + ( α + β ) {T}_{a} ( {t}_{0} , t ) \} {V}_{σ ( {t}_{0} )} ( Δ x ( {t}_{0} ) ) \\ {μ}^{{N}_{σ} ( {t}_{0} , t )} exp \{ - α ( t - {t}_{0} ) + ( α + β ) {N}_{σ} ( {t}_{0} , t ) \overline{τ} \} {V}_{σ ( {t}_{0} )} ( Δ x ( {t}_{0} ) ) ,\end{matrix} \qquad ( 17 )$$

where τ̅>0 represents the maximum action duration of the temperature limit controller; when τₐ>0 exists so that the controller switching process satisfies

$${N}_{σ} ( {t}_{0} , t ) \leq {N}_{0} + \frac{t - {t}_{0}}{{τ}_{a}} ,$$

N₀∈N and N represents a non-negative integer field, then the controller switching satisfies average dwell time switching, and

$$\begin{matrix}{V}_{σ ( t )} ( Δ x ( t ) ) \leq exp \{ [ ln μ + ( α + β ) \overline{τ} ] {N}_{σ} ( {t}_{0} , t ) - α t \} {V}_{σ ( {t}_{0} )} ( Δ x ( {t}_{0} ) ) \\ \leq exp \{ [ ln μ + ( α + β ) \overline{τ} ] {N}_{0} \} \\ \times exp \{ ( \frac{ln μ + ( α + β ) \overline{τ}}{{τ}_{a}} - α ) ( t - {t}_{0} ) \} {V}_{σ ( {t}_{0} )} ( Δ x ( {t}_{0} ) ) ;\end{matrix} \qquad ( 18 )$$

At this moment, when average dwell time satisfies the condition

$${τ}_{a} > \frac{( α + β ) \overline{τ} + ln μ}{α} , \qquad ( 19 )$$

then

$$\frac{ln μ + ( α + β ) \overline{τ}}{{τ}_{a}} - α < 0$$

and the Lyapunov function V_{σ}(Δx) decays to 0; at this moment, an aero-engine limit protection control system is stable:

To obtain a controller parameter condition that satisfies stability analysis, constructing the Lyapunov function for the closed-loop control system as follows:

$${V}_{i} ( Δ x ) = Δ {x}^{T} {U}_{i} Δ x , \qquad ( 20 )$$

where

$${U}_{i} = {P}_{i}^{- 1} ,$$

and Pᵢ represents a given positive definite symmetric matrix;

The derivative of Vᵢ(Δx) is taken, and from formula (12), the following can be obtained:

$$\begin{matrix}{\dot{V}}_{1} ( Δ x ) + α {V}_{1} ( Δ x ) = Δ {\dot{x}}^{T} {U}_{1} Δ x + Δ {x}^{T} {U}_{1} Δ \dot{x} + α Δ {x}^{T} {U}_{1} Δ x \\ = Δ {x}^{T} {\prod }_{1} Δ x ,\end{matrix}$$

$$where$$

$${\prod }_{1} = α {P}_{1} + ( \overline{A} {P}_{1} + \overline{B} {k}_{1} {Θ}_{1} {P}_{1} ) + {( \overline{A} {P}_{1} + \overline{B} {k}_{1} {Θ}_{1} {P}_{1} )}^{T} .$$

$$\begin{matrix}{\dot{V}}_{2} ( Δ x ) + β {V}_{2} ( Δ x ) = Δ {\dot{x}}^{T} {U}_{2} Δ x + Δ {x}^{T} {U}_{2} Δ \dot{x} - Δ {x}^{T} {U}_{2} Δ x \\ = Δ {x}^{T} {\prod }_{2} Δ x ,\end{matrix}$$

$$where$$

$${\prod }_{2} = - β {P}_{2} + ( \overline{A} {P}_{2} + \overline{B} {k}_{2} {Θ}_{2} {P}_{2} ) + {( \overline{A} {P}_{2} + \overline{B} {k}_{2} {Θ}_{2} {P}_{2} )}^{T} .$$

Therefore, for the given controller gains k₁ and k₂, when there are constants α>0, β>0 and μ>1 and the positive definite symmetric matrices P₁>0 and P₂>0 so that the following matrix inequalities are true,

$$α {P}_{1} + ( \overline{A} {P}_{1} + \overline{B} {k}_{1} {Θ}_{1} {P}_{1} ) + {( \overline{A} {P}_{1} + \overline{B} {k}_{1} {Θ}_{1} {P}_{1} )}^{T} \leq 0 , \qquad ( 21 )$$

$$- β {P}_{2} + ( \overline{A} {P}_{2} + \overline{B} {k}_{2} {Θ}_{2} {P}_{2} ) + {( \overline{A} {P}_{2} + \overline{B} {k}_{2} {Θ}_{2} {P}_{2} )}^{T} \leq 0 , \qquad ( 22 )$$

$${P}_{1} \leq μ {P}_{2} , {P}_{2} \leq μ {P}_{1} , \qquad ( 23 )$$

stability conditions (13), (14) and (15) are satisfied. Therefore, the aero-engine limit protection control system is stable.

### 5) Simulation Experiment of Temperature Limit Control in SIMULINK Software;

System identification is conducted for a two-rotor turbofan engine with high bypass ratio to obtain system matrices as follows:

$$\begin{matrix}A = [ \begin{matrix}- 1.7435 & 0.7462 \\ 0.508 & - 2.1737\end{matrix} ] , B = [ \begin{matrix}287.6485 \\ 891.1333\end{matrix} ] , \\ C = [ \begin{matrix}0.0244 & - 0.2665\end{matrix} ] , D = 410.4741 ;\end{matrix}$$

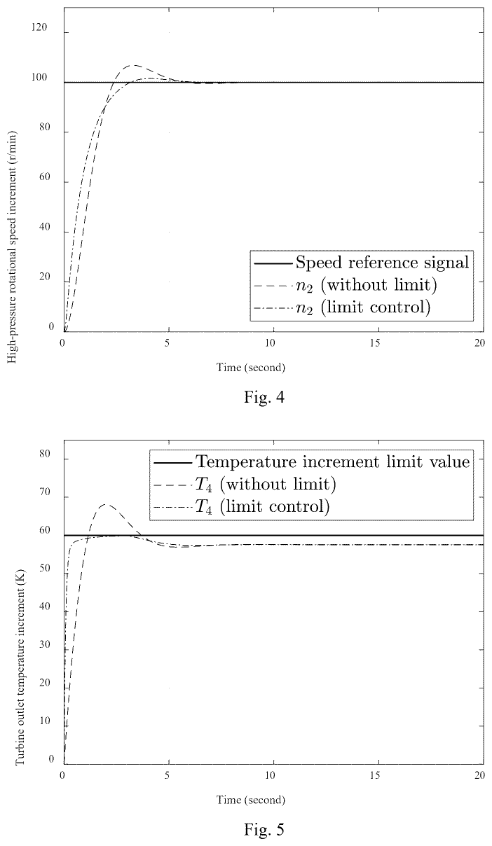

The reference value of the increment of high-pressure rotational speed is set to 100 r/min, the limit value of the increment of turbine outlet temperature is set to 60 K, parameter are set to α=0.2, β=0.1, μ=1.1 and N₀=1, and the maximum activation time of the temperature controller is set to 3 s. The inequality (19) is solved by MATLAB software to obtain the average dwell-time restriction τₐ>4.9766. Therefore, in an operating interval [0,20s], the maximum switching frequency of the controller is N_{σ}=5 times. Controller gains select k₁=0.002 and k₂=0.03, and the solvability of inequalities (21)-(23) is verified in YALMIP software. The simulation experiment is conducted in SIMULINK software. Experimental results are shown in FIG. 3 to FIG. 5. FIG. 3 shows controller switching signals of the aero-engine. It can be seen that the switching frequency of controllers satisfies the average dwell-time restriction, which guarantees the stability of the limit protection control system. FIG. 4 and FIG. 5 show the increment curve of high-pressure rotational speed and the increment curve of turbine outlet temperature of the aero-engine respectively. Under the action of the designed limit protection control method, the high-pressure rotational speed of the engine can accurately track the target value. When the turbine outlet temperature of the engine is close to the limit value, the corresponding limit controller is activated immediately to prevent the further occurrence of overtemperature failure to achieve the function of limit protection. In addition, compared with the condition without limit protection control, the proposed method can effectively reduce the overshoot of rotational speed, and improve the transient control performance while avoiding engine overtemperature.

An aero-engine limit protection control apparatus comprises:
a system identification module: used for system modeling and parameter identification of the aero-engine control system near an operating point by using real-time data of the aero-engine to obtain an aero-engine control system model which is convenient for controller design;
a main controller module: used for adjusting rotational speed of the aero-engine in a closed loop to satisfy the needs of aircraft for thrust change;
a temperature limit controller module: used for limiting the turbine outlet temperature of the aero-engine within a safety boundary to avoid the overtemperature operation of the aero-engine;
a stability analysis module: used for planning the switching process of the controller and verifying controller parameters to achieve the purpose of ensuring the stability of the aero-engine control system.

A computer-readable storage medium stores at least one instruction, at least one program, code set or instruction set, and the at least one instruction, the at least one program, the code set or the instruction set is loaded and executed by a processor to realize the above aero-engine limit protection control method.

A server comprises a processor and a memory, the memory stores at least one instruction, and the instruction is loaded and executed by the processor to realize the above aero-engine limit protection control method.

With respect to the safety control problem of the aero-engine, the present invention proposes a novel limit protection control method and applies the method to the temperature limit protection control of the turbofan aero-engine. The results indicate that the proposed method not only realizes the limit protection of the aero-engine in the transition process, but also theoretically analyzes the stability of the limit protection control system and improves the safety of the engine control system and the reliability of engineering application.
1. An aero-engine limit protection control method, comprising the following specific steps:
step 1: modeling of an aero-engine control system;
conducting linear system identification for an aero-engine according to input-output data near an operating point, and establishing a system model by using MATLAB software program calculation:

$$\{ \begin{matrix}\dot{n} ( t ) = An ( t ) + {Bw}_{f} ( t ) , \\ {T}_{4} ( t ) = Cn ( t ) + {Dw}_{f} ( t ) ,\end{matrix}$$

where n=[n₁ n₂]^{T}; n₁ and n₂ represent the increments of low-pressure rotational speed and high-pressure rotational speed of the aero-engine relative to a steady-state operating point respectively; w_{f} represents the fuel increment of the engine; T₄ represents the increment of the turbine outlet temperature of the engine; and A, B, C and D are identified system matrices; n represents a first-order derivative of n, and all the following characters with a dot represent the first-order derivative of the character;
step 2: design of a main controller;
extending a system state n and a control input w_{f} into a new state vector x to obtain an extended system with speed output as follows:

$$\{ \begin{matrix}\dot{x} = \overline{A} x + \overline{B} {u}_{f} , \\ {n}_{2} = {\overline{C}}_{1} x ,\end{matrix}$$

where

$$x = [ \begin{matrix}{n}^{T} & {{w}_{f}^{T} ]}^{T}\end{matrix}$$

and u_{f}=\dot{w}_{f} represent the derivatives of a fuel signal

$$\overline{A} = [ \begin{matrix}A & B \\ 0 & 0\end{matrix} ] ; \overline{B} = [ \begin{matrix}0 \\ I\end{matrix} ] ; {\overline{C}}_{1} = [ \begin{matrix}{C}_{1} & 0\end{matrix} ] ; {C}_{1} = [ \begin{matrix}0 & 1\end{matrix} ] ;$$

defining a state tracking error as Δx=x−xₛ, where xₛ represents a target value to be tracked;
designing the derivatives of the fuel signal that satisfy the conditions:

$${u}_{f} = {k}_{1} {Θ}_{1} Δ x ,$$

where k₁>0 represents a controller gain;

$${Θ}_{1} = [ {0}_{2 \times 1} 1 ] [ \begin{matrix}A & B \\ {C}_{1} & 0\end{matrix} ] ; {0}_{2 \times 1} = [ \begin{matrix}0 & 0\end{matrix} ] ;$$

calculating the main controller as follows:

$$\begin{matrix}{w}_{f} = {\int }_{0}^{t} {u}_{f} ( ε ) d ( ε ) \\ = {\int }_{0}^{t} {{k}_{1} [ {n}_{2} ( ε ) - {n}_{2 s} ( ε ) ]}^{T} dε\end{matrix} ;$$

where n₂ₛ represents a steady-state operating value of high-pressure rotational speed, and ε represents an integrating factor;
step 3: design of a temperature limit controller;
considering an extended system with temperature output as follows:

$$\{ \begin{matrix}\dot{x} = \overline{A} x + \overline{B} {u}_{f} , \\ {T}_{4} = {\overline{C}}_{2} x ,\end{matrix}$$

where C̅₂=[C D];
designing the derivatives of the fuel signal that satisfy the conditions:

$${u}_{f} = {k}_{2} {Θ}_{2} Δ x ,$$

where k₂>0 represents a controller gain;

$${Θ}_{2} = [ \begin{matrix}{0}_{2 \times 1} & 1\end{matrix} ] [ \begin{matrix}A & B \\ C & D\end{matrix} ] ;$$

calculating the temperature limit controller as follows:

$$\begin{matrix}{w}_{f} = {\int }_{0}^{t} {u}_{f} ( ε ) d ( ε ) \\ = {\int }_{0}^{t} {k}_{2} [ {T}_{4} ( ε ) - {T}_{4 s} ( ε ) ] d ε\end{matrix} ;$$

where T₄, represents the limit value of the increment of the turbine outlet temperature;
step 4: stability analysis;
providing dwell-time restriction, formulating controller switching rules, analyzing the stability of the limit protection control system and providing stability conditions; for a closed-loop control system, when there is a Lyapunov function V_{σ}(Δx) with σ(t)∈{1,2} representing a controller switching signal, and real numbers α>0 and μ>1, satisfying conditions:
1) within a running interval Tₛ(tₖ,tₖ₊₁) of the main controller,

$${\dot{V}}_{i} ( Δ x ) \leq - α {V}_{i} ( Δ x ) ,$$

2) within a running interval Tₐ(tₖ,tₖ₊₁) of the temperature limit controller,

$${\dot{V}}_{i} ( Δ x ) \leq β {V}_{i} ( Δ x ) ,$$

3) at a switching time t=tₖ of the controller,

$${V}_{i} ( Δ x ) \leq μ {V}_{j} ( Δ x ) ,$$

where i∈{1,2}, j∈{1,2}, i≠j, and β represents an upper bound of a system energy growth rate;
when the above three conditions are satisfied, the following inequalities are true,

$${V}_{σ ( t )} ( Δ x ( t ) ) \leq exp \{ - α {T}_{s} ( {t}_{\tilde{N}} , t ) + β {T}_{a} ( {t}_{\tilde{N}} , t ) \} {V}_{σ ( {t}_{\tilde{N}} )} ( Δ x ( {t}_{\tilde{N}} ) ) \leq μexp \{ - α {T}_{s} ( {t}_{\tilde{N}} , t ) + β {T}_{a} ( {t}_{\tilde{N}} , t ) \} {V}_{σ ( {t}_{\tilde{N} - 1} )} ( Δ x ( {t}_{\tilde{N}} ) ) \leq μexp \{ - α {T}_{s} ( {t}_{\tilde{N} - 1} , t ) + β {T}_{a} ( {t}_{\tilde{N} - 1} , t ) \} {V}_{σ ( {t}_{\tilde{N} - 1} )} ( Δ x ( {t}_{\tilde{N} - 1} ) ) \leq … \leq {μ}^{{N}_{σ} ( {t}_{0} , t )} exp \{ - α {T}_{s} ( {t}_{0} , t ) + β {T}_{a} ( {t}_{0} , t ) \} {V}_{σ ( {t}_{0} )} ( Δ x ( {t}_{0} ) )$$

where N_{σ}(t₀,t) represents the total number of switching within an interval [t₀, t); t_{Ñ} represents the last switching time within the interval [t₀,t);
due to t−t₀=Tₛ(t₀,t)+Tₐ(t₀,t), the following inequality can be obtained

$${V}_{σ ( t )} ( Δ x ( t ) ) \leq {μ}^{{N}_{σ} ( {t}_{0} , t )} exp \{ - α ( t - {t}_{0} ) + ( α + β ) {T}_{a} ( {t}_{0} , t ) \} {V}_{σ ( {t}_{0} )} ( Δ x ( {t}_{0} ) ) \leq {μ}^{{N}_{σ} ( {t}_{0} , t )} exp \{ - α ( t - {t}_{0} ) + ( α + β ) {T}_{a} ( {t}_{0} , t ) \overline{τ} \} {V}_{σ ( {t}_{0} )} ( Δ x ( {t}_{0} ) ) ,$$

where τ̅>0 represents the maximum action duration of the temperature limit controller;
when τₐ>0 exists so that the controller switching process satisfies

$${N}_{σ} ( {t}_{0} , t ) \leq {N}_{0} + \frac{t - {t}_{0}}{{τ}_{a}} ,$$

N₀∈N and N represents a non-negative integer field, then the controller switching satisfies average dwell time switching, and

$${V}_{σ ( t )} ( Δ x ( t ) ) \leq exp \{ [ ln μ + ( α + β ) \overline{τ} ] {N}_{0} \} \times exp \{ ( \frac{ln μ + ( α + β ) \overline{τ}}{{τ}_{a}} - α ) ( t - {t}_{0} ) \} {V}_{σ ( {t}_{0} )} ( Δ x ( {t}_{0} ) ) ;$$

at this moment, when average dwell time satisfies the condition:

$${τ}_{a} > \frac{( α + β ) \overline{τ} + ln μ}{α} ,$$

then

$$\frac{ln μ + ( α + β ) \overline{τ}}{{τ}_{a}} - α < 0$$

and the Lyapunov function V_{σ}(Δx) decays to 0; at this moment, an aero-engine limit protection control system is stable:
to obtain a controller parameter condition that satisfies stability analysis, constructing the Lyapunov function for the closed-loop control system as follows:

$${V}_{i} ( Δ x ) = Δ {x}^{T} {U}_{i} Δ x ,$$

where

$${U}_{i} = {P}_{i}^{- 1} ,$$

and Pᵢ represents a given positive definite symmetric matrix;
for the given controller gains k₁ and k₂, when there are constants α>0, β>0 and μ>1 and the positive definite symmetric matrices P₁>0 and P₂>0 so that the following matrix inequalities are true, the aero-engine limit protection control system is stable;

$$\begin{matrix}α {P}_{1} + ( \overline{A} {P}_{1} + \overline{B} {k}_{1} {Θ}_{1} {P}_{1} ) + {( \overline{A} {P}_{1} + \overline{B} {k}_{1} {Θ}_{1} {P}_{1} )}^{T} \leq 0 , \\ - β {P}_{2} + ( \overline{A} {P}_{2} + \overline{B} {k}_{2} {Θ}_{2} {P}_{2} ) + {( \overline{A} {P}_{2} + \overline{B} {k}_{2} {Θ}_{2} {P}_{2} )}^{T} \leq 0 , \\ {P}_{1} \leq μ {P}_{2} , {P}_{2} \leq μ {P}_{1} ;\end{matrix}$$

step 5: a control simulation experiment of a turbofan aero-engine to analyze control performance.
2. The aero-engine limit protection control method according to claim 1, wherein the process of the step 1 is realized in MATLAB software; the process of the step 2 is realized in MATLAB software; the process of the step 3 is realized in MATLAB software; the inequality solving process of the step 4 is realized in YALMIP software; and the simulation experiment of the step 5 is conducted in SIMULINK software.
3. An aero-engine limit protection control apparatus, comprising:
a system identification module: used for system modeling and parameter identification of the aero-engine control system near an operating point by using real-time data of the aero-engine to obtain an aero-engine control system model which is convenient for controller design;
a main controller module: used for adjusting rotational speed of the aero-engine in a closed loop to satisfy the needs of aircraft for thrust change;
a temperature limit controller module: used for limiting the turbine outlet temperature of the aero-engine within a safety boundary to avoid the overtemperature operation of the aero-engine;
a stability analysis module: used for planning the switching process of the controller and verifying controller parameters to achieve the purpose of ensuring the stability of the aero-engine control system.
4. A computer-readable storage medium, storing at least one instruction, at least one program, code set or instruction set, wherein the at least one instruction, the at least one program, the code set or the instruction set is loaded and executed by a processor to realize the aero-engine limit protection control method according to any one of claims 1-2.
5. A server, comprising a processor and a memory, wherein the memory stores at least one instruction, and the instruction is loaded and executed by the processor to realize the aero-engine limit protection control method according to any one of claims 1-2.

The present invention provides an aero-engine limit protection control method and apparatus, a storage medium and a device, which belongs to the technical field of aero-engine control. Through the design of a main controller and a limit controller, the present invention realizes the effects of tracking of high-pressure rotational speed and the limit of turbine outlet temperature respectively. A Lyapunov function is designed. The stability of a closed-loop system is analyzed under the average dwell-time restriction. Controller parameter conditions that satisfy stability analysis are obtained by solving inequalities. The proposed method not only realizes the purpose of limit protection control of the aero-engine in a transition stage and improves the safety of an aero-engine control system, but also theoretically analyzes the stability of the aero-engine limit protection control system and improves the reliability of engineering application.

1. An aero-engine limit protection control method, comprising the following specific steps:
step 1: modeling of an aero-engine control system;
conducting linear system identification for an aero-engine according to input-output data near an operating point, and establishing a system model by using MATLAB software program calculation:
$$\{ \begin{matrix}\dot{n} ( t ) = An ( t ) + {Bw}_{f} ( t ) , \\ {T}_{4} ( t ) = Cn ( t ) + {Dw}_{f} ( t ) ,\end{matrix}$$
where n=[n₁ n₂]^{T}; n₁ and n₂ represent the increments of low-pressure rotational speed and high-pressure rotational speed of the aero-engine relative to a steady-state operating point respectively; w_{f} represents the fuel increment of the engine; T₄ represents the increment of the turbine outlet temperature of the engine; and A, B, C and D are identified system matrices; \dot{n} represents a first-order derivative of n, and all the following characters with a dot represent the first-order derivative of the character;
step 2: design of a main controller;
extending a system state n and a control input w_{f} into a new state vector X to obtain an extended system with speed output as follows:
$$\{ \begin{matrix}\dot{x} = \overline{A} x + \overline{B} {u}_{f} , \\ {n}_{2} = {\overline{C}}_{1} x ,\end{matrix}$$
where
$$x = {[ \begin{matrix}{n}^{T} & {w}_{f}^{T}\end{matrix} ]}^{T}$$
and u_{f}=\dot{w}_{f} represent the derivatives of a fuel signal;
$$\overline{A} = [ \begin{matrix}A & B \\ 0 & 0\end{matrix} ] ; \overline{B} = [ \begin{matrix}0 \\ I\end{matrix} ] ; {\overline{C}}_{1} = [ \begin{matrix}{C}_{1} & 0\end{matrix} ] ; {C}_{1} = [ \begin{matrix}0 & 1\end{matrix} ] ;$$
defining a state tracking error as Δx=x−xₛ, where xₛ represents a target value to be tracked; designing the derivatives of the fuel signal that satisfy the conditions:
$${u}_{f} = {k}_{1} {Θ}_{1} Δ x ,$$
where k₁>0 represents a controller gain;
$${Θ}_{1} = [ \begin{matrix}{0}_{2 \times 1} & 1\end{matrix} ] [ \begin{matrix}A & B \\ {C}_{1} & 0\end{matrix} ] ; {0}_{2 \times 1} = [ \begin{matrix}0 & 0\end{matrix} ] ;$$
calculating the main controller as follows:
$$\begin{matrix}{w}_{f} = {\int }_{0}^{t} {u}_{f} ( ε ) d ε \\ = {\int }_{0}^{t} {{k}_{1} [ {n}_{2} ( ε ) - {n}_{2 s} ( ε ) ]}^{T} d ε ;\end{matrix}$$
where n₂ₛ represents a steady-state operating value of high-pressure rotational speed, and ε represents an integrating factor;
step 3: design of a temperature limit controller;
considering an extended system with temperature output as follows:
$$\{ \begin{matrix}\dot{x} = \overline{A} x + \overline{B} {u}_{f} , \\ {T}_{4} = {\overline{C}}_{2} x ,\end{matrix}$$
where C̅₂=[C D];
designing the derivatives of the fuel signal that satisfy the conditions:
$${u}_{f} = {k}_{2} {Θ}_{2} Δ x ,$$
where k₂>0 represents a controller gain;
$${Θ}_{2} = [ {0}_{2 \times 1} 1 ] [ \begin{matrix}A & B \\ C & D\end{matrix} ] ;$$
calculating the temperature limit controller as follows:
$$\begin{matrix}{w}_{f} = {\int }_{0}^{t} {u}_{f} ( ε ) d ε \\ = {\int }_{0}^{t} {k}_{2} [ {T}_{4} ( ε ) - {T}_{4 s} ( ε ) ] d ε ;\end{matrix}$$
where T₄ₛ represents the limit value of the increment of the turbine outlet temperature;
step 4: stability analysis;
providing dwell-time restriction, formulating controller switching rules, analyzing the stability of the limit protection control system and providing stability conditions; for a closed-loop control system, when there is a Lyapunov function V_{σ}(Δx) with σ(t)∈{1,2} representing a controller switching signal, and real numbers α>0 and μ>1, satisfying conditions:
1) within a running interval Tₛ(tₖ,tₖ₊₁) of the main controller,
$${\dot{V}}_{i} ( Δ x ) \leq - α {V}_{i} ( Δ x ) ,$$
2) within a running interval Tₐ(tₖ,tₖ₊₁) of the temperature limit controller,
$${\dot{V}}_{i} ( Δ x ) \leq β {V}_{i} ( Δ x ) ,$$
3) at a switching time t=tₖ of the controller,
Vᵢ(Δx)≤μVⱼ(Δx),
where i∈{1,2}, j∈{1,2}, i≠j, and β represents an upper bound of a system energy growth rate;
when the above three conditions are satisfied, the following inequalities are true,
$$\begin{matrix}{V}_{σ ( t )} ( Δ x ( t ) ) \leq exp \{ - α {T}_{s} ( {t}_{\tilde{N}} , t ) + β {T}_{a} ( {t}_{\tilde{N}} , t ) \} {V}_{σ ( {t}_{\tilde{N}} )} ( Δ x ( {t}_{\tilde{N}} ) ) \\ \leq μexp \{ - α {T}_{s} ( {t}_{\tilde{N}} , t ) + β {T}_{a} ( {t}_{\tilde{N}} , t ) \} {V}_{σ ( {t}_{\tilde{N} - 1} )} ( Δ x ( {t}_{\tilde{N}} ) ) \\ \leq μexp \{ - α {T}_{s} ( {t}_{\tilde{N} - 1} , t ) + β {T}_{a} ( {t}_{\tilde{N} - 1} , t ) \} {V}_{σ ( {t}_{\tilde{N} - 1} )} ( Δ x ( {t}_{\tilde{N} - 1} ) ) \\ \leq … \\ \leq {μ}^{{N}_{σ} ( {t}_{0} , t )} exp \{ - α {T}_{s} ( {t}_{0} , t ) + β {T}_{a} ( {t}_{0} , t ) \} {V}_{σ ( {t}_{0} )} ( Δ x ( {t}_{0} ) )\end{matrix}$$
where N_{σ}(t₀,t) represents the total number of switching within an interval [t₀,t); t_{Ñ} represents the last switching time within the interval [t₀,t); due to t−t₀=Tₛ(t₀,t)+Tₐ(t₀,t), the following inequality can be obtained
$$\begin{matrix}{V}_{σ ( t )} ( Δ x ( t ) ) \leq {μ}^{{N}_{σ} ( {t}_{0} , t )} exp \{ - α ( t - {t}_{0} ) + ( α + β ) {T}_{a} ( {t}_{0} , t ) \} {V}_{σ ( {t}_{0} )} ( Δ x ( {t}_{0} ) ) \\ \leq {μ}^{{N}_{σ} ( {t}_{0} , t )} exp \{ - α ( t - {t}_{0} ) + ( α + β ) {N}_{σ} ( {t}_{0} , t ) \overline{τ} \} {V}_{σ ( {t}_{0} )} ( Δ x ( {t}_{0} ) ) ,\end{matrix}$$
where τ̅>0 represents the maximum action duration of the temperature limit controller;
when τₐ>0 exists so that the controller switching process satisfies
$${N}_{σ} ( {t}_{0} , t ) \leq {N}_{0} + \frac{t - {t}_{0}}{{τ}_{a}} ,$$
N₀∈N and N represents a non-negative integer field, then the controller switching satisfies average dwell time switching, and
$${V}_{σ ( t )} ( Δ x ( t ) ) \leq exp \{ [ ln μ + ( α + β ) \overline{τ} ] {N}_{0} \} \times exp \{ ( \frac{ln μ + ( α + β ) \overline{τ}}{{τ}_{a}} - α ) ( t - {t}_{0} ) \} {V}_{σ ( {t}_{0} )} ( Δ x ( {t}_{0} ) ) ;$$
at this moment, when average dwell time satisfies the condition:
$${τ}_{a} > \frac{( α + β ) \overline{τ} + ln μ}{α} ,$$
then
$$\frac{ln μ + ( α + β ) \overline{τ}}{{τ}_{a}} - α < 0$$
and the Lyapunov function V_{σ}(Δx) decays to 0; at this moment, an aero-engine limit protection control system is stable:
to obtain a controller parameter condition that satisfies stability analysis, constructing the Lyapunov function for the closed-loop control system as follows:
$${V}_{i} ( Δ x ) = Δ {x}^{T} {U}_{i} Δ x ,$$
where Uᵢ=Pᵢ⁻¹, and Pᵢ represents a given positive definite symmetric matrix;
for the given controller gains k₁ and k₂, when there are constants α>0, β>0 and μ>1 and the positive definite symmetric matrices P₁>0 and P₂>0 so that the following matrix inequalities are true, the aero-engine limit protection control system is stable;
$$α {P}_{1} + ( \overline{A} {P}_{1} + \overline{B} {k}_{1} {Θ}_{1} {P}_{1} ) + {( \overline{A} {P}_{1} + \overline{B} {k}_{1} {Θ}_{1} {P}_{1} )}^{T} \leq 0 , - β {P}_{2} + ( \overline{A} {P}_{2} + \overline{B} {k}_{2} {Θ}_{2} {P}_{2} ) + {( \overline{A} {P}_{2} + \overline{B} {k}_{2} {Θ}_{2} {P}_{2} )}^{T} \leq 0 , {P}_{1} \leq μ {P}_{2} , {P}_{2} \leq μ {P}_{1} ;$$
step 5: a control simulation experiment of a turbofan aero-engine to analyze control performance.

2. The aero-engine limit protection control method according to claim 1, wherein the process of the step 1 is realized in MATLAB software; the process of the step 2 is realized in MATLAB software; the process of the step 3 is realized in MATLAB software; the inequality solving process of the step 4 is realized in YALMIP software; and the simulation experiment of the step 5 is conducted in SIMULINK software.
